(19) United States
(12) Patent Application Publication
(10) Pub. No.: US 2024/0213951 A1
(43) Pub. Date: Jun. 27, 2024

(54) ACOUSTIC WAVE DEVICE

(71) Applicant: Murata Manufacturing Co., Ltd., Nagaokakyo-shi (JP)

(72) Inventor: Kazumasa HARUTA, Nagaokakyo-shi (JP)

(21) Appl. No.: 18/596,747

(22) Filed: Mar. 6, 2024

Related U.S. Application Data
(63) Continuation of application No. PCT/JP2022/033498, filed on Sep. 7, 2022.

(30) Foreign Application Priority Data
Sep. 8, 2021 (JP) 2021-146313

(51) Int. Cl. H03H 9/08; H03H 9/10; H03H 9/13; H03H 9/17

(52) U.S. Cl. CPC H03H 9/08; H03H 9/105; H03H 9/13; H03H 9/173; H03H 9/176

(57) ABSTRACT

An acoustic wave device includes a support, a piezoelectric layer having anisotropy of a coefficient of linear expansion, and including first and second main surfaces, and first and second electrodes on the first and second main surfaces of the piezoelectric layer. The support includes a hollow portion. At least a portion of the first and second electrodes overlaps the hollow portion. A heat dissipation structure including the support is provided on the first main surface side of the piezoelectric layer. One of a first and second region includes a high heat dissipation region. Each of the first and second electrodes includes an electrode layer having a higher coefficient of linear expansion than a maximum coefficient of linear expansion of the piezoelectric layer.

### CROSS REFERENCE TO RELATED APPLICATIONS

This application claims the benefit of priority to Japanese Patent Application No. 2021-146313 filed on Sep. 8, 2021 and is a Continuation Application of PCT Application No. PCT/JP2022/033498 filed on Sep. 7, 2022. The entire contents of each application are hereby incorporated herein by reference.

### BACKGROUND OF THE INVENTION

### 1. Field of the Invention

The present invention relates to acoustic wave devices.

### 2. Description of the Related Art

In the related art, acoustic wave devices have been widely used as a filter of a mobile phone. An example of the acoustic wave devices is disclosed in Japanese Unexamined Patent Application Publication No. 2020-108030. In this acoustic wave device, a piezoelectric film is provided on a board. Examples of a material of the piezoelectric film include aluminum nitride. An upper electrode is provided on one main surface of the piezoelectric film, and a lower electrode is provided on the other main surface of the piezoelectric film. The upper electrode and the lower electrode face each other with the piezoelectric film interposed therebetween. A void is provided in the board. A portion of the lower electrode facing the upper electrode faces the board with the void interposed therebetween. Residual stress of the lower electrode is tensile stress, and residual stress of the upper electrode is compressive stress. Thus, the piezoelectric film curves downward. Heat is dissipated from the downward curving piezoelectric film to the board side.

However, in a case where the piezoelectric film has anisotropy of a coefficient of linear expansion, the piezoelectric film may have a distorted shape depending on configurations of the upper electrode and the lower electrode. For example, in a case where lithium tantalate or lithium niobate is used in the piezoelectric film, the piezoelectric film has anisotropy of the coefficient of linear expansion. In the example according to Japanese Unexamined Patent Application Publication No. 2020-108030, the upper electrode and the lower electrode are formed of ruthenium. A magnitude of a coefficient of linear expansion of ruthenium is between the maximum coefficient of linear expansion and the minimum coefficient of linear expansion of lithium tantalate or lithium niobate. In this case, the shape of the piezoelectric film is not a simple convex shape and may include wavy curves. Thus, it is difficult to sufficiently increase heat dissipation.

### SUMMARY OF THE INVENTION

Example embodiments of the present invention provide acoustic wave devices in each of which a piezoelectric layer is able to be more securely structured into a convex shape and heat dissipation is able be effectively increased.

An example embodiment of the present invention provides an acoustic wave device including a support, a piezoelectric layer on the support, having anisotropy of a coefficient of linear expansion, and including a first main surface and a second main surface facing each other, and a first electrode on the first main surface of the piezoelectric layer and a second electrode on the second main surface and facing the first electrode, in which the support includes a hollow portion, and at least a portion of the first electrode and the second electrode overlaps the hollow portion in a plan view, on a first main surface side of the piezoelectric layer, the support is positioned, and a heat dissipation structure including the support is provided, the first main surface of the piezoelectric layer includes a first region in which the first electrode is provided, the second main surface includes a second region in which the second electrode is provided, and one of the first region and the second region is a high heat dissipation region having higher heat dissipation of the heat dissipation structure than another of the first region and the second region, each of the first electrode and the second electrode includes an electrode layer having a higher coefficient of linear expansion than a maximum coefficient of linear expansion of the piezoelectric layer, and, where a product of a thickness average value of a coefficient of linear expansion and a total thickness in an electrode is referred to as a linear expansion of the electrode, the linear expansion of one of the first electrode and the second electrode provided in the high heat dissipation region is higher than the linear expansion of the other of the first electrode and the second electrode.

Example embodiments of the present invention provide acoustic wave devices in each of which a piezoelectric layer is able to be more securely structured into a convex shape and heat dissipation is able to be effectively increased.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a cross-sectional front view of an acoustic wave device according to a first example embodiment of the present invention.

FIG. 2 is a plan view of the acoustic wave device according to the first example embodiment of the present invention.

FIG. 3 is a cross-sectional front view for describing deformation of a piezoelectric layer into a convex shape at a high temperature in the first example embodiment of the present invention.

FIG. 4 is a cross-sectional front view of an acoustic wave device according to a first modified example of the first example embodiment of the present invention.

FIG. 5 is a cross-sectional front view of an acoustic wave device according to a second modified example of the first example embodiment of the present invention.

FIG. 6 is a cross-sectional front view of an acoustic wave device according to a third modified example of the first example embodiment of the present invention.

FIG. 7 is a cross-sectional front view of an acoustic wave device according to a second example embodiment of the present invention.

FIG. 8 is a cross-sectional front view of an acoustic wave device according to a third example embodiment of the present invention.

FIG. 9 is a cross-sectional front view of an acoustic wave device according to a fourth example embodiment of the present invention.

FIG. 10 is a cross-sectional front view of an acoustic wave device according to a fifth example embodiment of the present invention.

### DETAILED DESCRIPTION OF THE EXAMPLE EMBODIMENTS

Hereinafter, the present invention will be clarified by describing example embodiments of the present invention with reference to the drawings.

Each example embodiment described in the present specification is an example, and configurations can be partially replaced or combined with each other between different example embodiments.

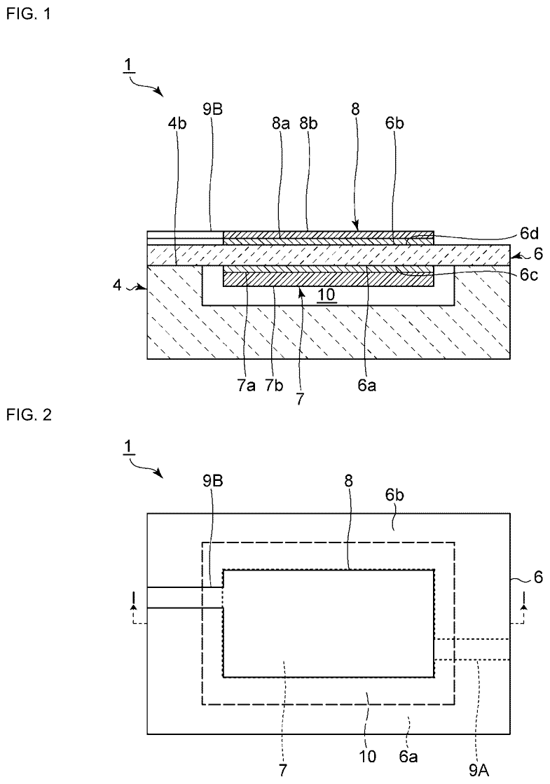

FIG. 1 is a cross-sectional front view of an acoustic wave device according to a first example embodiment of the present invention. FIG. 2 is a plan view of the acoustic wave device according to the first example embodiment. FIG. 1 is a cross-sectional view taken along line I-I in FIG. 2.

An acoustic wave device 1 illustrated in FIGS. 1 and 2 is, for example, a bulk acoustic wave (BAW) element. Specifically, as illustrated in FIG. 1, the acoustic wave device 1 includes a support board 4 and a piezoelectric layer 6. The piezoelectric layer 6 is provided on the support board 4. The support board 4 defines a support. In the present example embodiment, the support board 4 and the piezoelectric layer 6 are directly bonded to each other. However, the support may include a bonding layer. In this case, the support is bonded to the piezoelectric layer 6 using the bonding layer.

The piezoelectric layer 6 includes a first main surface 6a and a second main surface 6b. The first main surface 6a and the second main surface 6b face each other. The first main surface 6a, of the first main surface 6a and the second main surface 6b, is a main surface on the support board 4 side. The piezoelectric layer 6 has anisotropy of a coefficient of linear expansion. For example, lithium niobate or lithium tantalate can be used as a material of the piezoelectric layer 6.

The support board 4 includes a recessed portion and a support portion 4b. The support portion 4b surrounds the recessed portion. The recessed portion is a hollow portion 10 of the support board 4. The piezoelectric layer 6 is provided on the support portion 4b to close the hollow portion 10. A bottom surface of the recessed portion of the support board 4 is a facing portion of the support board 4. The facing portion is a part facing the first main surface 6a of the piezoelectric layer 6.

The support board 4 is, for example, a silicon board in the present example embodiment. A material of the support board 4 is not limited to the above. For example, aluminum oxide, crystal, alumina, sapphire, silicon nitride, aluminum nitride, silicon carbide, diamond, or gallium nitride can also be used. Thermal conductivity of the support board 4 is preferably higher than thermal conductivity of the piezoelectric layer 6. By doing so, heat dissipation can be increased.

The first main surface 6a of the piezoelectric layer 6 includes a first region 6c. A first electrode 7 is provided in the first region 6c. The second main surface 6b includes a second region 6d. A second electrode 8 is provided in the second region 6d. The first electrode 7 and the second electrode 8 face each other with the piezoelectric layer 6 interposed therebetween. In a plan view, an overlapping portion between the first electrode 7 and the second electrode 8 is an excitation region. An acoustic wave is excited in the excitation region. In the present specification, the plan view refers to a direction of view from the top in FIG. 1. In the plan view, all of the first electrode 7 and the second electrode 8 overlap with the hollow portion 10 of the support board 4. The first electrode 7 is positioned in the hollow portion 10. In the plan view, at least a portion of the first electrode 7 and the second electrode 8 may overlap with the hollow portion 10.

As illustrated in FIG. 2, a first extraction wire 9A is provided on the first main surface 6a of the piezoelectric layer 6. The first extraction wire 9A is connected to the first electrode 7. A second extraction wire 9B is provided on the second main surface 6b. The second extraction wire 9B is connected to the second electrode 8. The first extraction wire 9A and the second extraction wire 9B are connected to potentials different from each other.

With reference to FIG. 1, a heat dissipation structure is provided in the acoustic wave device 1. More specifically, the heat dissipation structure of the acoustic wave device 1 includes the support board 4 as the support. In a case where the acoustic wave is excited, heat is generated in the excitation region. This heat can be dissipated using the heat dissipation structure. Heat dissipation of the heat dissipation structure varies between the first region 6c of the first main surface 6a and the second region 6d of the second main surface 6b in the piezoelectric layer 6. A region having higher heat dissipation of the first region 6c and the second region 6d is a high heat dissipation region. In the acoustic wave device 1, the heat dissipation structure is provided on only the first main surface 6a side of the first main surface 6a and the second main surface 6b. Thus, the first region 6c is the high heat dissipation region.

Each of the first electrode 7 and the second electrode 8 is a multilayer body including a plurality of electrode layers. Specifically, the first electrode 7 includes a first electrode layer 7a and a second electrode layer 7b. The second electrode 8 also includes a first electrode layer 8a and a second electrode layer 8b. The first electrode layers of the first electrode 7 and the second electrode 8 are, for example, Pt layers. The second electrode layers of the first electrode 7 and the second electrode 8 are, for example, Al layers. Each first electrode layer is positioned closest to the piezoelectric layer 6 side among the plurality of electrode layers.

As a combination of thicknesses of the Pt layer and the Al layer, for example, the thickness of the Pt layer may be greater than or equal to about 50 μm and less than or equal to about 150 μm, and the thickness of the Al layer may be about 200 μm. Alternatively, for example, in a case where the thickness of the Pt layer is greater than or equal to about 25 μm and less than or equal to about 75 μm, the thickness of the Al layer may be about 100 μm. Of course, a combination of materials of the first electrode layer and the second electrode layer is not limited to the Pt layer and the Al layer. For example, the combination of the materials of the first electrode layer and the second electrode layer may be any of a Ti layer and an Al layer, a Pt layer and an AlCu layer, a Ru layer and a Cr layer, and an Al layer and a W layer. The first electrode layer and the second electrode layer may be bonded to each other using, for example, a thin Ti layer.

In a case where the piezoelectric layer 6 is, for example, a lithium niobate layer, a coefficient of linear expansion of the Al layer is higher than the maximum coefficient of linear expansion of the piezoelectric layer 6. The same applies to a case where the piezoelectric layer 6 is, for example, a lithium tantalate layer. Materials, the number of layers, and an order of lamination of the first electrode 7 and the second electrode 8 are not limited to the above. That is, the Al layer having a higher coefficient of linear expansion than the piezoelectric layer 6 may be the first electrode layer or the second electrode layer. In a case where the Al layer having a high coefficient of linear expansion is the first electrode layer, a layer having a large difference in the coefficient of linear expansion with the first electrode layer is present near the first electrode layer. Thus, a convex shape can be more securely provided. Meanwhile, in a case where the Al layer having a high coefficient of linear expansion is the second electrode layer and the Pt layer having a lower coefficient of linear expansion than the Al layer is the first electrode layer, a layer having a large difference in the coefficient of linear expansion with the first electrode layer is not present near the first electrode layer. Thus, a convex shape can be provided while a crack and the like caused by stress are reduced or prevented. A coefficient of linear expansion of at least one electrode layer in each of the first electrode 7 and the second electrode 8 may be higher than the maximum coefficient of linear expansion of the piezoelectric layer 6.

Hereinafter, the term “linear expansion” will be used. The linear expansion refers to a product of a thickness average value of a coefficient of linear expansion and a total thickness in an electrode. More specifically, in a case where the number of electrode layers of the first electrode 7 is m layers and a thickness of the j-th electrode layer of the first electrode 7 is t1ⱼ, a total thickness of the first electrode 7 is Σt1ⱼ (1≤j≤m). In a case where a coefficient of linear expansion of the j-th electrode layer of the first electrode 7 is α1ⱼ, a thickness average value of the coefficient of linear expansion of the first electrode 7 is Σ(α1ⱼ×t1ⱼ)/Σt1ⱼ (1≤j≤m). Linear expansion of the first electrode 7 is Σ(α1ⱼ×t1ⱼ) (1≤j≤m). Similarly, in a case where the number of electrode layers of the second electrode 8 is n layers, a thickness of the k-th electrode layer of the second electrode 8 is t2ₖ, and a coefficient of linear expansion of the k-th electrode layer of the second electrode 8 is α2ₖ, linear expansion of the second electrode 8 is Σ(α2ₖ×t2ₖ) (1≤j≤m). Here, each of j, k, m, and n is any integer.

In the present example embodiment, the linear expansion of the first electrode 7 is α1₁t1₁+α1₂t1₂, and the linear expansion of the second electrode 8 is α2₁t2₁+α2₂t2₂. The first electrode layer 7a of the first electrode 7 and the first electrode layer 8a of the second electrode 8 are formed of the same material and have the same thickness. Thus, α1₁t1₁=α2₁t2₁ is established. Meanwhile, while the second electrode layer 7b of the first electrode 7 and the second electrode layer 8b of the second electrode 8 are formed of the same material, a thickness of the second electrode layer 7b of the first electrode 7 is greater than a thickness of the second electrode layer 8b of the second electrode 8. Thus, α1₂t1₂>α2₂t2₂ is established. Accordingly, the linear expansion of the first electrode 7 is greater than the linear expansion of the second electrode 8.

Features of the present example embodiment include the following configurations. 1) The piezoelectric layer 6 has anisotropy of the coefficient of linear expansion. 2) Each of the first electrode 7 and the second electrode 8 includes an electrode layer having a higher coefficient of linear expansion than the maximum coefficient of linear expansion of the piezoelectric layer 6. 3) The linear expansion of the electrode provided in the high heat dissipation region of the first electrode 7 and the second electrode 8 is greater than the linear expansion of the other electrode out of the first electrode 7 and the second electrode 8. As described above, in the present example embodiment, the high heat dissipation region is the first region 6c of the first main surface 6a in the piezoelectric layer 6. Thus, the electrode provided in the high heat dissipation region of the first electrode 7 and the second electrode 8 is the first electrode 7.

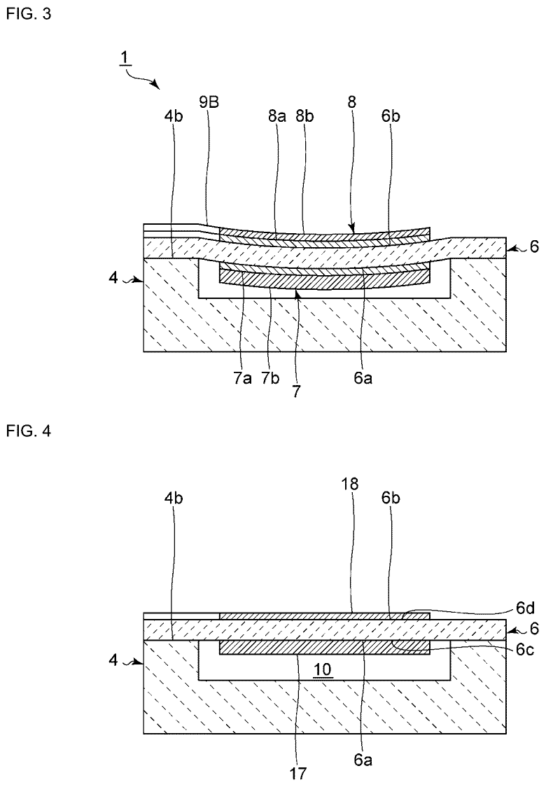

In a case where the acoustic wave is excited in the acoustic wave device 1 and the piezoelectric layer 6 reaches a high temperature, the piezoelectric layer 6 deforms as illustrated in FIG. 3. By providing the acoustic wave device 1 with the above configurations, a shape of the piezoelectric layer 6 can be more securely formed into a convex shape regardless of the anisotropy of the coefficient of linear expansion of the piezoelectric layer 6. More specifically, the shape of the piezoelectric layer 6 can be formed into a convex shape to the support board 4 side as the heat dissipation structure. By doing so, the piezoelectric layer 6 can be more securely and effectively brought close to the heat dissipation structure, and the heat dissipation can be effectively increased.

In the present example embodiment, the first electrode 7 and the second electrode 8 are, for example, multilayer bodies. The first electrode 7 is provided in the high heat dissipation region. In this case, the thickness of the second electrode layer 7b having a higher coefficient of linear expansion than the maximum coefficient of linear expansion of the piezoelectric layer 6 in the first electrode 7 is preferably greater than the thickness of the second electrode layer 8b having a higher coefficient of linear expansion than the maximum coefficient of linear expansion of the piezoelectric layer 6 in the second electrode 8. Accordingly, the linear expansion of the first electrode 7 can be more securely and easily increased above the linear expansion of the second electrode 8. Thus, the heat dissipation can be more securely, easily, and effectively increased.

It is possible that the first electrode 7 and the second electrode 8 are not multilayer bodies. In a first modified example of the first example embodiment illustrated in FIG. 4, a first electrode 17 and a second electrode 18 include single electrode layers. In this case, coefficients of linear expansion of both of the first electrode 17 and the second electrode 18 may be higher than the maximum coefficient of linear expansion of the piezoelectric layer 6. While the first electrode 17 and the second electrode 18 are, for example, Al layers in the present modified example, the first electrode 17 and the second electrode 18 may be, for example, any of a Mo layer, a Ru layer, and a W layer. Furthermore, a thickness of the first electrode 17 may be greater than a thickness of the second electrode 18. Thus, linear expansion of the first electrode 17 is greater than linear expansion of the second electrode 18. Even in the present modified example, the piezoelectric layer 6 can be more securely structured into a convex shape, and the heat dissipation can be effectively increased, as in the first example embodiment.

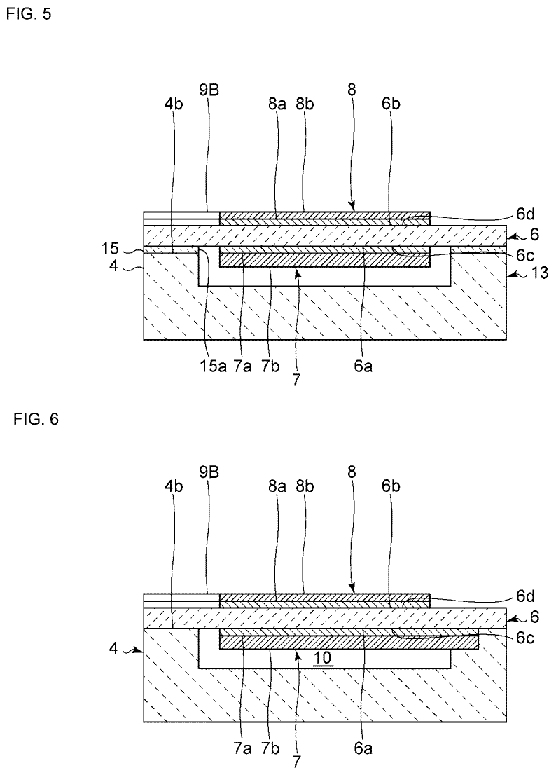

The support may include a bonding layer. In a second modified example of the first example embodiment illustrated in FIG. 5, a support 13 includes the support board 4 and a bonding layer 15. The bonding layer 15 is provided on the support portion 4b of the support board 4. The piezoelectric layer 6 is provided on the bonding layer 15. The bonding layer 15 has a frame shape. More specifically, the bonding layer 15 includes a through-hole 15a. A hollow portion of the support 13 includes the recessed portion of the support board 4 and the through-hole 15a of the bonding layer 15. For example, silicon oxide, silicon nitride, or tantalum oxide can be used as a material of the bonding layer 15. Even in the present modified example, the piezoelectric layer 6 can be more securely structured into a convex shape, and the heat dissipation can be effectively increased, as in the first example embodiment.

In the first example embodiment, all of the first electrode 7 and the second electrode 8 overlap with the hollow portion 10 in the plan view. Of course, the present invention is not limited thereto. In a third modified example of the first example embodiment illustrated in FIG. 6, the first electrode 7 extends to the support portion 4b of the support board 4. More specifically, a portion of the first electrode 7 is positioned between the support portion 4b and the piezoelectric layer 6. Even in the present modified example, the piezoelectric layer 6 can be more securely structured into a convex shape, and the heat dissipation can be effectively increased, as in the first example embodiment. In addition, since the first electrode 7 is in contact with the support portion 4b, the heat dissipation can be further increased.

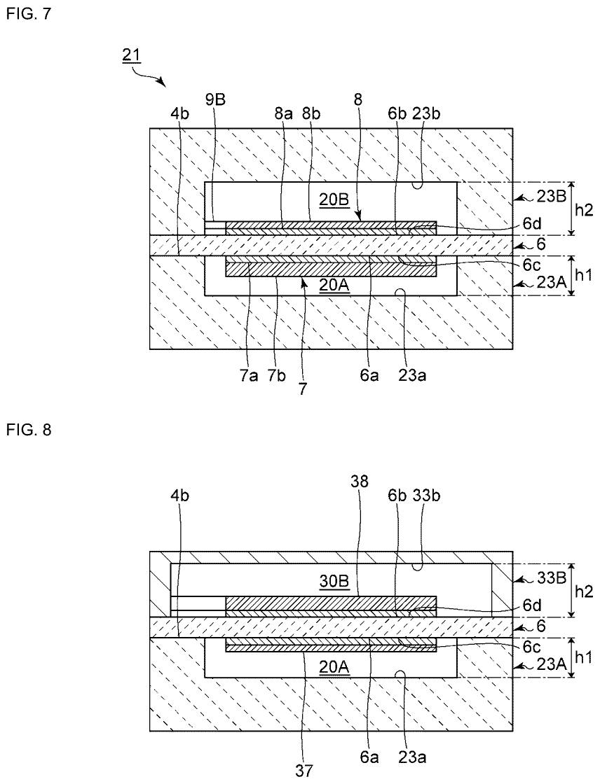

FIG. 7 is a cross-sectional front view of an acoustic wave device according to a second example embodiment of the present invention.

The present example embodiment is different from the first example embodiment in that the heat dissipation structure is provided on both of the first main surface 6a side and the second main surface 6b side of the piezoelectric layer 6. Except for this point, an acoustic wave device 21 of the present example embodiment has the same or substantially the same configuration as the acoustic wave device 1 of the first example embodiment.

A first heat dissipation structure 23A is provided on the first main surface 6a side of the piezoelectric layer 6. The first heat dissipation structure 23A has the same or substantially the same configuration as the support in the first example embodiment. Of course, the first heat dissipation structure 23A may include a member other than the support. A hollow portion in the first heat dissipation structure 23A is a first hollow portion 20A illustrated in FIG. 7. The first heat dissipation structure 23A includes a first facing portion 23a. The first facing portion 23a is a portion facing the first main surface 6a of the piezoelectric layer 6.

A second heat dissipation structure 23B is provided on the second main surface 6b side of the piezoelectric layer 6. The second heat dissipation structure 23B is, for example, a cap. More specifically, the second heat dissipation structure 23B includes a recessed portion. The recessed portion is a second hollow portion 20B of the second heat dissipation structure 23B illustrated in FIG. 7. The cap defining the second heat dissipation structure 23B is directly bonded to the piezoelectric layer 6. Of course, the cap may include a bonding layer. In this case, the cap is bonded to the piezoelectric layer 6 using the bonding layer. The second heat dissipation structure 23B includes a second facing portion 23b. The second facing portion 23b is a portion facing the second main surface 6b of the piezoelectric layer 6.

A heat dissipation structure of the acoustic wave device 21 includes the first heat dissipation structure 23A and the second heat dissipation structure 23B. In the present example embodiment, the first heat dissipation structure 23A and the second heat dissipation structure 23B are made of the same material. Of course, the first heat dissipation structure 23A and the second heat dissipation structure 23B may be made of materials different from each other.

A height h1 of the first hollow portion 20A in the first heat dissipation structure 23A and a height h2 of the second hollow portion 20B in the second heat dissipation structure 23B are different from each other. The height h1 of the first hollow portion 20A is a dimension from the first facing portion 23a of the first heat dissipation structure 23A to a portion of the piezoelectric layer 6 bonded to the first heat dissipation structure 23A along a direction parallel or substantially parallel to a thickness direction of the piezoelectric layer 6. Similarly, the height h2 of the second hollow portion 20B is a dimension from the second facing portion 23b of the second heat dissipation structure 23B to a portion of the piezoelectric layer 6 bonded to the second heat dissipation structure 23B along the direction parallel or substantially parallel to the thickness direction of the piezoelectric layer 6.

As in the first example embodiment, the first electrode 7 is provided in the first region 6c of the first main surface 6a in the piezoelectric layer 6. The second electrode 8 is provided in the second region 6d of the second main surface 6b. In the acoustic wave device 21, the heat dissipation of the heat dissipation structure in the first region 6c is higher than the heat dissipation of the heat dissipation structure in the second region 6d. That is, heat of the piezoelectric layer 6 is more likely to be dissipated from the first heat dissipation structure 23A than from the second heat dissipation structure 23B. Details will be described below.

For example, in a case where one main surface of the piezoelectric layer faces the hollow portion of the heat dissipation structure, the heat dissipation of the heat dissipation structure on the main surface is mainly determined by the height of the hollow portion and the heat dissipation in the facing portion of the heat dissipation structure. As the height of the hollow portion is decreased, a distance between the main surface and the portion facing the main surface in the hollow portion is decreased. Thus, as the height of the hollow portion is decreased, the heat dissipation is increased. Furthermore, as the heat dissipation in the facing portion of the heat dissipation structure is increased, the heat dissipation of the heat dissipation structure on the main surface is increased. For example, as thermal conductivity of the facing portion is increased, the heat dissipation of the facing portion is increased, and the heat dissipation of the heat dissipation structure on the main surface is also increased.

In the present example embodiment, the height h1 of the first hollow portion 20A is smaller than the height h2 of the second hollow portion 20B. Thus, a distance between the first facing portion 23a in the first heat dissipation structure 23A and the first main surface 6a in the piezoelectric layer 6 is smaller than a distance between the second facing portion 23b in the second heat dissipation structure 23B and the second main surface 6b in the piezoelectric layer 6. In addition, the first facing portion 23a and the second facing portion 23b are made of the same material. Thus, the heat dissipation of the first heat dissipation structure 23A in the first region 6c of the first main surface 6a is higher than the heat dissipation of the second heat dissipation structure 23B in the second region 6d of the second main surface 6b. The high heat dissipation region of the acoustic wave device 21 is the first region 6c.

The first electrode 7 and the second electrode 8 are configured in the same or substantially the same manner as those of the first example embodiment. Thus, each of the first electrode 7 and the second electrode 8 includes an electrode layer having a higher coefficient of linear expansion than the maximum coefficient of linear expansion of the piezoelectric layer 6, and the linear expansion of the first electrode 7 is higher than the linear expansion of the second electrode 8. Accordingly, the shape of the piezoelectric layer 6 can be more securely structured into a convex shape to the first heat dissipation structure 23A in a case where the piezoelectric layer 6 reaches a high temperature. As described above, the heat of the piezoelectric layer 6 is more likely to be dissipated from the first heat dissipation structure 23A than from the second heat dissipation structure 23B. Accordingly, the heat dissipation in the acoustic wave device 21 can be effectively increased.

FIG. 8 is a cross-sectional front view of an acoustic wave device according to a third example embodiment of the present invention.

The present example embodiment is different from the second example embodiment in that a configuration of a second heat dissipation structure 33B is provided and the high heat dissipation region of the piezoelectric layer 6 is the second region 6d of the second main surface 6b. Furthermore, the present example embodiment is different from the second example embodiment in that linear expansion of a second electrode 38 is higher than linear expansion of the first electrode 37. Except for these points, the acoustic wave device of the present example embodiment has the same or substantially the same configuration as the acoustic wave device 21 of the second example embodiment.

The first electrode 37 has the same or substantially the same configuration as the second electrode 8 in the second example embodiment. The second electrode 38 has the same or substantially the same configuration as the first electrode 7 in the second example embodiment. Thus, the linear expansion of the second electrode 38 is higher than the linear expansion of the first electrode 37.

As described above, in a case where one main surface of the piezoelectric layer faces the hollow portion of the heat dissipation structure, the heat dissipation of the heat dissipation structure on the main surface is mainly determined by the height of the hollow portion and the heat dissipation in the facing portion of the heat dissipation structure. In the present example embodiment, the height h1 of the first hollow portion 20A of the first heat dissipation structure 23A is smaller than the height h2 of a second hollow portion 30B of the second heat dissipation structure 33B. This contributes to making the heat of the piezoelectric layer 6 likely to be dissipated from the first heat dissipation structure 23A. In addition, thermal conductivity of the cap as the second heat dissipation structure 33B is higher than thermal conductivity of the support as the first heat dissipation structure 23A. Thus, the heat dissipation in the second facing portion 33b of the second heat dissipation structure 33B is higher than the heat dissipation in the first facing portion 23a of the first heat dissipation structure 23A. This contributes to making the heat of the piezoelectric layer 6 likely to be dissipated from the second heat dissipation structure 33B.

In the present example embodiment, a contribution made by a difference in the thermal conductivity between the first heat dissipation structure 23A and the second heat dissipation structure 33B is higher than a contribution made by the height of the hollow portion, as the contribution to the heat dissipation in the piezoelectric layer 6. Thus, the heat dissipation of the second heat dissipation structure 33B in the second region 6d of the second main surface 6b is higher than the heat dissipation of the first heat dissipation structure 23A in the first region 6c of the first main surface 6a in the piezoelectric layer 6.

The high heat dissipation region of the piezoelectric layer 6 in the present example embodiment is the second region 6d of the second main surface 6b. The second electrode 38 is provided in the second region 6d. Meanwhile, the first electrode 37 is provided in the first region 6c of the first main surface 6a. Furthermore, the linear expansion of the second electrode 38 is higher than the linear expansion of the first electrode 37. By doing so, the shape of the piezoelectric layer 6 can be more securely structured into a convex shape to the second heat dissipation structure 33B side in a case where the piezoelectric layer 6 reaches a high temperature. Accordingly, the heat dissipation in the acoustic wave device can be effectively increased.

For example, Al, Cu, Ag, Au, aluminum nitride, silicon carbide, diamond, or gallium nitride can be used as a material of the cap.

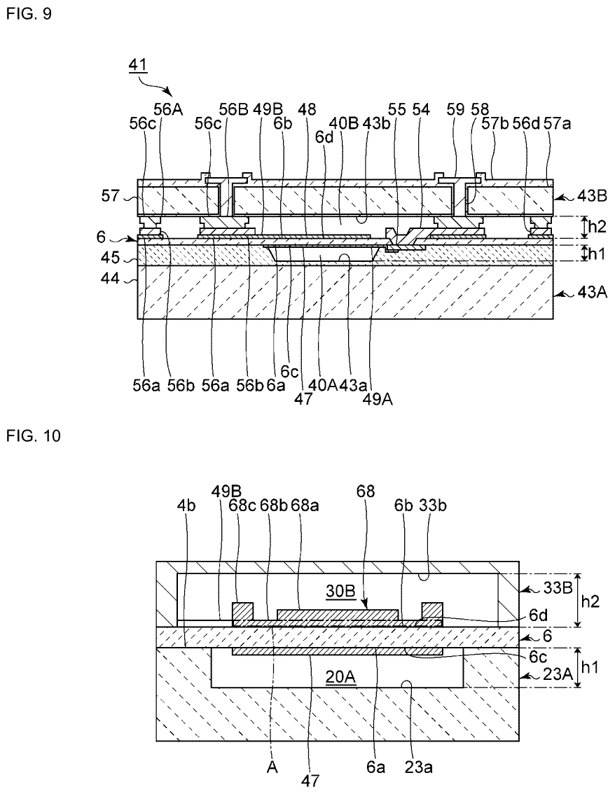

FIG. 9 is a cross-sectional front view of an acoustic wave device according to a fourth example embodiment of the present invention.

An acoustic wave device 41 includes a first heat dissipation structure 43A and a second heat dissipation structure 43B. The first heat dissipation structure 43A includes a support board 44 and a bonding layer 45. A recessed portion is provided in the bonding layer 45. The recessed portion is a first hollow portion 40A of the first heat dissipation structure 43A. The first hollow portion 40A is provided in only the bonding layer 45. The piezoelectric layer 6 is provided on the bonding layer 45.

The second heat dissipation structure 43B includes a first support layer 56A, a plurality of second support layers 56B, and a lid portion 57. The first support layer 56A is a support layer in the present invention. The first support layer 56A has a frame shape. The second support layer 56B has a columnar shape.

The first support layer 56A surrounds a second electrode 48 on the second main surface 6b of the piezoelectric layer 6. More specifically, the first support layer 56A includes a cavity 56d. The second electrode 48 is positioned in the cavity 56d. The plurality of second support layers 56B are provided in a portion positioned in the cavity 56d on the second main surface 6b. In the plan view, the first hollow portion 40A of the first heat dissipation structure 43A is positioned inside the cavity 56d. In the plan view, the second support layer 56B does not overlap with the first hollow portion 40A.

The lid portion 57 is provided to close the cavity 56d on the first support layer 56A and on the plurality of second support layers 56B. Accordingly, a second hollow portion 40B of the second heat dissipation structure 43B is provided. The lid portion 57 includes a main body portion 57a and a dielectric layer 57b. The main body portion 57a has a plate shape. In the present example embodiment, the dielectric layer 57b is provided on both main surfaces of the main body portion 57a.

The main body portion 57a is, for example, a silicon board in the present example embodiment. A material of the main body portion 57a is not limited to the above. For example, aluminum oxide, crystal, alumina, sapphire, silicon nitride, aluminum nitride, silicon carbide, diamond, or gallium nitride can also be used. Thermal conductivity of the main body portion 57a is preferably higher than the thermal conductivity of the piezoelectric layer 6. By doing so, the heat dissipation can be increased.

The dielectric layer 57b is, for example, a silicon oxide layer in the present example embodiment. A material of the dielectric layer 57b is not limited to the above. For example, silicon nitride or tantalum oxide can also be used. The dielectric layer 57b is not necessarily provided.

Even in the present example embodiment, the first heat dissipation structure 43A includes a first facing portion 43a. As described above, the first facing portion 43a is a portion facing the first main surface 6a of the piezoelectric layer 6. Similarly, the second heat dissipation structure 43B also includes a second facing portion 43b. The second facing portion 43b is a portion facing the second main surface 6b of the piezoelectric layer 6. In the first facing portion 43a, the bonding layer 45 and the support board 44 are laminated with each other. In the second facing portion 43b, the dielectric layer 57b and the main body portion 57a are laminated with each other.

In the acoustic wave device 41, the heat dissipation in the second facing portion 43b is higher than the heat dissipation in the first facing portion 43a. In addition, the height h2 of the second hollow portion 40B is greater than the height h1 of the first hollow portion 40A. In the acoustic wave device 41, a contribution made by a difference in the heat dissipation between the first heat dissipation structure 43A and the second heat dissipation structure 43B is higher than a contribution made by the height of the hollow portion, as the contribution to the heat dissipation in the piezoelectric layer 6. Thus, the heat dissipation of the second heat dissipation structure 43B in the second region 6d of the second main surface 6b is higher than the heat dissipation of the first heat dissipation structure 43A in the first region 6c of the first main surface 6a in the piezoelectric layer 6.

The high heat dissipation region of the piezoelectric layer 6 in the present example embodiment is the second region 6d of the second main surface 6b. The second electrode 48 is provided in the second region 6d. Meanwhile, a first electrode 47 is provided in the first region 6c of the first main surface 6a. Furthermore, linear expansion of the second electrode 48 is higher than linear expansion of the first electrode 47. By doing so, the shape of the piezoelectric layer 6 can be more securely structured into a convex shape to the second heat dissipation structure 43B side in a case where the piezoelectric layer 6 reaches a high temperature. Accordingly, the heat dissipation in the acoustic wave device 41 can be effectively increased.

Hereinafter, configurations of the present example embodiment will be described in more detail.

The first support layer 56A and the second support layer 56B are multilayer bodies. More specifically, the first support layer 56A includes a first layer 56a, a second layer 56b, and a third layer 56c. The first layer 56a is provided on the second main surface 6b of the piezoelectric layer 6. The second layer 56b is provided on the first layer 56a. The third layer 56c is provided on the second layer 56b. Any of the first layer 56a, the second layer 56b, and the third layer 56c is a metal layer. The second support layer 56B is also made of the same material as the first support layer 56A and includes the first layer 56a, the second layer 56b, and the third layer 56c. The first support layer 56A and the second support layers 56B may have different layer configurations.

A second extraction wire 49B is connected to the first layer 56a of one of two second support layers 56B illustrated in FIG. 9. The first layer 56a and the second electrode 48 are electrically connected through the second extraction wire 49B.

A wiring electrode 54 is connected to the second layer 56b of the other of the two second support layers 56B. The wiring electrode 54 is an electrode provided on the second main surface 6b of the piezoelectric layer 6. A part of the wiring electrode 54 is connected to a wiring electrode 55 by passing through the piezoelectric layer 6. The wiring electrode 55 is an electrode provided between the piezoelectric layer 6 and the bonding layer 45. The wiring electrode 55 is connected to a first extraction wire 49A. The second layer 56b and the first electrode 47 are electrically connected through the wiring electrode 54, the wiring electrode 55, and the first extraction wire 49A.

A plurality of through-holes are provided in the main body portion 57a of the lid portion 57. More specifically, each of the plurality of through-holes is provided to extend to the second support layers 56B. A through-electrode 58 is provided in each of the plurality of through-holes. One end of each of the through-electrodes 58 is connected to the second support layers 56B. A plurality of electrode pads 59 are provided to be connected to the respective other ends of the plurality of through-electrodes 58. In the present example embodiment, each through-electrode 58 and the electrode pad 59 connected thereto are provided as a single body.

The first electrode 47 is electrically connected to an outside through the first extraction wire 49A, the wiring electrode 55, the wiring electrode 54, the second support layers 56B, the through-electrodes 58, and the electrode pads 59. The second electrode 48 is electrically connected to the outside through the second extraction wire 49B, the second support layers 56B, the through-electrodes 58, and the electrode pads 59.

The dielectric layer 57b in the lid portion 57 is also provided in the through-holes of the main body portion 57a. More specifically, the dielectric layer 57b is provided between the main body portion 57a and the through-electrodes 58. The dielectric layer 57b positioned on both main surfaces of the main body portion 57a and the dielectric layer 57b positioned in the through-holes of the main body portion 57a are provided as a single body. Furthermore, the same dielectric layer as the dielectric layer 57b covers an outer periphery of each electrode pad 59. However, the dielectric layer is not necessarily provided.

As illustrated in FIG. 9, each of the first electrode 47 and the second electrode 48 includes a single electrode layer. The first electrode 47 and the second electrode 48 are made of the same material. A coefficient of linear expansion of each of the first electrode 47 and the second electrode 48 is higher than the maximum coefficient of linear expansion of the piezoelectric layer 6. Since a thickness of the second electrode 48 is greater than a thickness of the first electrode 47, the linear expansion of the second electrode 48 is higher than the linear expansion of the first electrode 47. Layer configurations of the first electrode 47 and the second electrode 48 are not limited to the above.

FIG. 10 is a cross-sectional front view of an acoustic wave device according to a fifth example embodiment of the present invention.

The present example embodiment is different from the third example embodiment in configurations of the first electrode 47, a second electrode 68, a first extraction electrode, and the second extraction wire 49B. Except for the point, the acoustic wave device of the present example embodiment has the same or substantially the same configuration as the acoustic wave device of the third example embodiment.

As in the fourth example embodiment, the first electrode 47 and the second extraction wire 49B include single electrode layers. While an illustration is not provided, the first extraction electrode also includes a single electrode layer, as in the fourth example embodiment.

Meanwhile, the second electrode 68 includes a first portion 68a, a second portion 68b, and a third portion 68c. The first portion 68a is a portion including a center in a portion overlapping with the excitation region in the plan view. The second portion 68b is a portion around the first portion 68a. The third portion 68c is a portion around the second portion 68b and is a portion including an outer periphery in the portion overlapping with the excitation region in the plan view. Thicknesses of the first portion 68a and the third portion 68c are greater than a thickness of the second portion 68b. Furthermore, in the present example embodiment, the thickness of the third portion 68c is greater than the thickness of the first portion 68a.

The second electrode 68 corresponds to a configuration of the second electrode 8 in which a thickness near a center portion and a thickness near an outer periphery in the first example embodiment are increased. In this case, the thickness of the second portion 68b of the second electrode 68 corresponds to a thickness of the second electrode 8 in the first example embodiment. That is, a portion of the second electrode 68 surrounded by dot-dashed line A in FIG. 10 is a portion corresponding to the first electrode layer 8a and the second electrode layer 8b of the second electrode 8 in the first example embodiment. More specifically, the portion of the second electrode 68 surrounded by dot-dashed line A is a portion that includes a portion of the first portion 68a, the entire second portion 68b, and a portion of the third portion 68c and that has the same or substantially the same thickness as the thickness of the second portion 68b.

The first electrode 47 and the second electrode 68 are made of the same material. A coefficient of linear expansion of each of the first electrode 47 and the second electrode 68 is higher than the maximum coefficient of linear expansion of the piezoelectric layer 6. A thickness of the second electrode 68 is greater than the thickness of the first electrode 47 in at least the first portion 68a and the third portion 68c. Thus, linear expansion of the second electrode 68 is higher than the linear expansion of the first electrode 47. Furthermore, as in the third example embodiment, the second region 6d of the second main surface 6b in the piezoelectric layer 6 is the high heat dissipation region. The second electrode 68 is provided in the high heat dissipation region. By doing so, the shape of the piezoelectric layer 6 can be more securely formed into a convex shape to the second heat dissipation structure 33B side in a case where the piezoelectric layer 6 reaches a high temperature. Accordingly, the heat dissipation in the acoustic wave device can be effectively increased.

Even in a case where the second electrode 68 has the first portion 68a, the second portion 68b, and the third portion 68c, the second electrode 68 may be a multilayer body. For example, a thickness of an electrode layer of the second electrode 68 closest to the piezoelectric layer 6 side may be the same or substantially the same as the thickness of the second portion 68b. In this case, the electrode layer includes a portion of the first portion 68a, the entire second portion 68b, and a part of the third part 68c. An electrode layer defining the remaining portion of the first portion 68a and an electrode layer defining the remaining portion of the third portion 68c may be provided on the electrode layer.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a support;
a piezoelectric layer on the support, having anisotropy of a coefficient of linear expansion, and including a first main surface and a second main surface facing each other; and
a first electrode on the first main surface of the piezoelectric layer and a second electrode on the second main surface and that faces the first electrode; wherein
the support includes a hollow portion, and at least a portion of the first electrode and the second electrode overlaps the hollow portion in a plan view;
the support is provided on a first main surface side of the piezoelectric layer, and a heat dissipation structure including the support is provided;
the first main surface of the piezoelectric layer includes a first region in which the first electrode is provided, the second main surface includes a second region in which the second electrode is provided, and one of the first region and the second region is a high heat dissipation region having higher heat dissipation of the heat dissipation structure than the other of the first region and the second region;
each of the first electrode and the second electrode includes an electrode layer having a higher coefficient of linear expansion than a maximum coefficient of linear expansion of the piezoelectric layer; and
where a product of a thickness average value of a coefficient of linear expansion and a total thickness in an electrode is referred to as a linear expansion of the electrode, the linear expansion of one of the first electrode and the second electrode provided in the high heat dissipation region is higher than the linear expansion of the other of the first electrode and the second electrode.

2. The acoustic wave device according to claim 1, wherein a thickness of the electrode layer having a higher coefficient of linear expansion than the maximum coefficient of linear expansion of the piezoelectric layer in the one of the first electrode and the second electrode provided in the high heat dissipation region is greater than a thickness of the electrode layer having a higher coefficient of linear expansion than the maximum coefficient of linear expansion of the piezoelectric layer in the other of the first electrode and the second electrode.

3. The acoustic wave device according to claim 1, wherein
each of the first electrode and the second electrode includes a first electrode layer and a second electrode layer;
in each of the first electrode and the second electrode, the first electrode layer and the second electrode layer are laminated with each other, and the first electrode layer is closer to a piezoelectric layer side than the second electrode layer; and
the first electrode layer of each of the first electrode and the second electrode has a higher coefficient of linear expansion than the maximum coefficient of linear expansion of the piezoelectric layer.

4. The acoustic wave device according to claim 1, wherein
each of the first electrode and the second electrode includes a first electrode layer and a second electrode layer;
in each of the first electrode and the second electrode, the first electrode layer and the second electrode layer are laminated with each other, and the first electrode layer is closer to a piezoelectric layer side than the second electrode layer; and
the second electrode layer of each of the first electrode and the second electrode has a higher coefficient of linear expansion than the maximum coefficient of linear expansion of the piezoelectric layer.

5. The acoustic wave device according to claim 1, wherein
the heat dissipation structure is provided on only the first main surface side of the first main surface and the second main surface of the piezoelectric layer; and
the first region is the high heat dissipation region.

6. The acoustic wave device according to claim 1, wherein
the heat dissipation structure is provided on the first main surface side of the piezoelectric layer and includes a first heat dissipation structure including the support and a second heat dissipation structure on the second main surface side;
the hollow portion of the support is a first hollow portion, and the second heat dissipation structure includes a second hollow portion in which the second electrode is positioned; and
the first heat dissipation structure includes a first facing portion facing the first main surface of the piezoelectric layer, and the second heat dissipation structure includes a second facing portion facing the second main surface of the piezoelectric layer.

7. The acoustic wave device according to claim 6, wherein heat dissipation of the first facing portion and heat dissipation of the second facing portion are different from each other.

8. The acoustic wave device according to claim 6, wherein a height of the first hollow portion and a height of the second hollow portion are different from each other.

9. The acoustic wave device according to claim 6, further comprising:
a cap provided on the second main surface of the piezoelectric layer; wherein
the second heat dissipation structure includes the cap.

10. The acoustic wave device according to claim 6, further comprising:
a support layer surrounding the second electrode on the second main surface of the piezoelectric layer; and
a lid portion on the support layer; wherein
the second heat dissipation structure includes the support layer and the lid portion.

11. The acoustic wave device according to claim 1, wherein the support includes a support board, and the first electrode is in contact with the support board.

12. The acoustic wave device according to claim 1, wherein
the support includes a support board and a bonding layer on the support board, and the piezoelectric layer is provided on the bonding layer; and
at least a portion of the hollow portion of the support is provided in the bonding layer.

13. The acoustic wave device according to claim 1, wherein the piezoelectric layer is a lithium niobate layer or a lithium tantalate layer.

14. The acoustic wave device according to claim 11, wherein the support board includes silicon.

15. The acoustic wave device according to claim 3, wherein the first electrode layer includes Pt.

16. The acoustic wave device according to claim 3, wherein the second electrode layer includes Al.

17. The acoustic wave device according to claim 3, wherein a
a thickness of the first electrode layer is greater than or equal to about 50 μm and less than or equal to about 150 μm; and
a thickness of the second electrode layer is about 200 μm.

18. The acoustic wave device according to claim 3, wherein
a thickness of the first electrode layer is greater than or equal to about 25 μm and less than or equal to about 75 μm; and
a thickness of the second electrode layer is about 100 μm.

19. The acoustic wave device according to claim 12, wherein the bonding layer has a frame shape.

20. The acoustic wave device according to claim 12, wherein the bonding layer includes silicon oxide, silicon nitride, or tantalum oxide.
